(19) United States
(12) Patent Application Publication
(10) Pub. No.: US 2013/0319731 A1
(43) Pub. Date: Dec. 5, 2013

(54) PRINTED CIRCUIT BOARD OF SEMICONDUCTOR PACKAGE FOR DECREASING NOISE BY ELECTROMAGNETIC INTERFERENCE

(71) Applicant: STS SEMICONDUCTOR & TELECOMMUNICATIONS CO., LTD., Chungcheongnam-do (KR)

(72) Inventor: Yun Im Lee, Chungcheongnam-do (KR)

(73) Assignee: STS Semiconductor & Telecommunications Co., Ltd., Chungcheongnam-do (KR)

(21) Appl. No.: 13/846,342

(22) Filed: Mar. 18, 2013

(30) Foreign Application Priority Data
May 30, 2012 (KR) 10-2012-0057466

(51) Int. Cl. H05K 1/02

(52) U.S. Cl. CPC H05K 1/0216
USPC 174/251

(57) ABSTRACT

A printed circuit board for a semiconductor package which is capable of reducing noise by electromagnetic interference (EMI), including: an upper circuit layer in which a first circuit pattern is formed; an intermediate circuit layer that is disposed below the upper circuit layer and has a second circuit pattern formed therein; a lower circuit layer that is disposed below the intermediate circuit layer and has a third circuit pattern formed therein; an insulating layer disposed between the first and second circuit patterns and between the second and third circuit patterns; vias that vertically connect the first, second and third circuit patterns; and EMI blocking vias that are arranged along edge portions of the first, second and third circuit patterns and are connected to a ground layer.

### CROSS-REFERENCE TO RELATED PATENT APPLICATION

This application claims the benefit of Korean Patent Application No. 10-2012-0057466, filed on May 30, 2012, in the Korean Intellectual Property Office, the disclosure of which is incorporated herein in its entirety by reference.

### BACKGROUND OF THE INVENTION

1. Field of the Invention

Aspects of the present invention relate to a semiconductor package, and more particularly, to a printed circuit board (PCB) for a semiconductor package which is used as a base frame of the semiconductor package.

2. Description of the Related Art

Electronic devices that use alternating current (AC) electric energy generate noise by electromagnetic waves to some extent. Such noise appears in the form of radiation of electromagnetic waves through space or in the form of conduction through wires, such as power lines, and thus, interrupts a stable operation of electronic devices.

Semiconductor packages that have a three-dimensional structure, such as a multi-chip package (MCP), a system in package (SIP), or a package on package (POP) and operate at a high speed have emerged. In these semiconductor packages, such as MCP, SIP, and POP, as an operating speed becomes faster or as a distance between adjacent semiconductor devices of a semiconductor package decreases, noise by electromagnetic interference (EMI) occurs more often in proportion thereto. In this regard, a printed circuit board (PCB), which is used as a base frame of a semiconductor package, has a compact printed circuit pattern into which the noise by EMI is transmitted, and thus, the PCB serves as a noise source by EMI.

### SUMMARY OF THE INVENTION

Aspects of the present invention provide a printed circuit board (PCB) for a semiconductor package to which a high-frequency power is applied, which is capable of reducing noise by electromagnetic interference (EMI).

According to an aspect of the present invention, there is provided a printed circuit board for a semiconductor package, the printed circuit board including: an upper circuit layer in which a first circuit pattern is formed; an intermediate circuit layer that is disposed below the upper circuit layer and has a second circuit pattern formed therein; a lower circuit layer that is disposed below the intermediate circuit layer and has a third circuit pattern formed therein; an insulating layer disposed between the first and second circuit patterns and between the second and third circuit patterns; vias that vertically connect the first, second and third circuit patterns; and electromagnetic interference (EMI) blocking vias that are arranged along edge portions of the first, second and third circuit patterns and are connected to a ground layer.

According to an experimental example of the present inventive concept, the EMI blocking vias penetrate the upper circuit layer, the intermediate circuit layer, and the lower circuit layer, and the EMI blocking vias have a closed curve shape, viewed from planes of the upper and lower circuit layers.

According to an experimental example of the present inventive concept, the printed circuit board includes at least two of the intermediate circuit layers, and at least two of the intermediate circuit layers include a ground layer and a power layer.

The EMI blocking vias are arranged so as to surround a power terminal in the first, second and third circuit patterns, and the width of the EMI blocking vias is larger than a width of the vias.

### BRIEF DESCRIPTION OF THE DRAWINGS

The above and other features and advantages of the present invention will become more apparent by describing in detail exemplary embodiments thereof with reference to the attached drawings in which:

FIG. 1 is a plan view of a printed circuit board (PCB) for a semiconductor package, according to an embodiment of the present invention;

FIG. 2 is a bottom view of a PCB for a semiconductor package, according to an embodiment of the present invention;

FIG. 3 is a cross-sectional view of a PCB for a semiconductor package, according to an embodiment of the present invention; and

FIG. 4 is a block diagram illustrating an electronic system including a PCB for a semiconductor package, according to an embodiment of the present invention.

### DETAILED DESCRIPTION OF THE INVENTION

Reference will now be made in detail to example embodiments, examples of which are illustrated in the accompanying drawings. However, example embodiments are not limited to the embodiments illustrated hereinafter, and various changes in form and details may be made herein. Rather, these embodiments are provided so that this disclosure will be thorough and complete, and will fully convey the scope of the invention to those skilled in the art. In addition, the size of each element in the drawings can be exaggerated for convenience of explanation.

It will be understood that when an element is referred to as being “on” another element or “connected” to another element, it can be directly on the other element or directly connected to the other element or intervening elements may also be present. In contrast, when an element is referred to as being “directly on” or “directly connected to” another element, there are no intervening elements present. The same may be applied to the terms used to explain a relationship between elements, for example, “between” and “directly between.”

Although terms, such as ‘first’ and ‘second’, can be used to describe various elements, the elements cannot be limited by the terms. The terms can be used to classify a certain element from another element. For example, a first element can be named a second element without leaving from the right scope of the inventive concept, and likely the second element can be named the first element.

An expression in the singular includes an expression in the plural unless they are clearly different from each other in a context. In the application, it should be understood that terms, such as ‘include’ and ‘have’, are used to indicate the existence of implemented feature, number, step, operation, element, part, or a combination of them without excluding in advance the possibility of existence or addition of one or more other features, numbers, steps, operations, elements, parts, or combinations of them.

All terms used herein including technical or scientific terms have the same meaning as those generally understood by those of ordinary skill in the art unless they are defined differently. It should be understood that terms generally used, which are defined in a dictionary, have the same meaning as in a context of related technology, and the terms are not understood as ideal or excessively formal meaning unless they are clearly defined in the application.

Hereinafter, exemplary embodiments of the present invention will be described in detail with reference to the accompanying drawings. Throughout the drawings, like reference numerals refer to like elements.

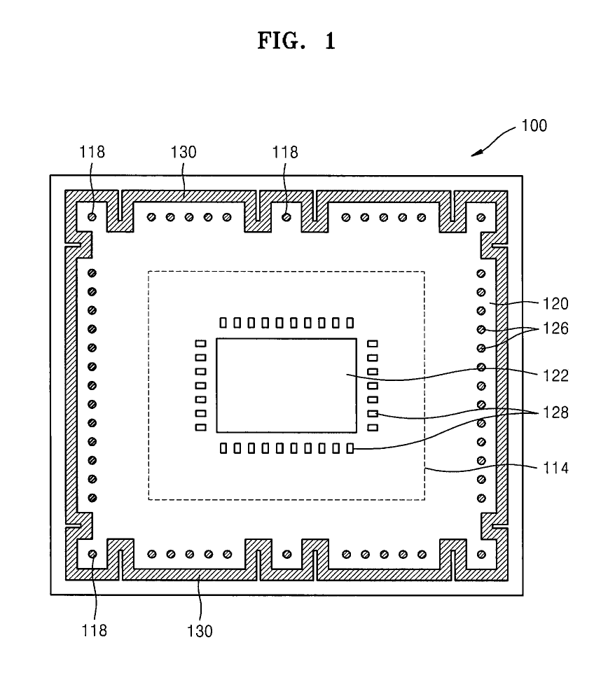

FIG. 1 is a plan view of a printed circuit board (PCB) 100 for a semiconductor package, according to an embodiment of the present invention.

Referring to FIG. 1, the PCB 100 may be a multi-layered substrate having at least four layers. The PCB 100 includes an upper circuit layer 120 disposed at an upper portion thereof. The upper circuit layer 120 may include a chip mount area 122 on which a semiconductor chip is to be mounted, at a center area thereof. Bond fingers 128 are arranged along an edge of the chip mount area 122 so as to connect to wires. A region 114 illustrated by a dashed line denotes a portion on which an encapsulation member of the semiconductor package is to be formed.

A plurality of vias 118 and 126 that vertically connect printed circuit patterns (not shown) with each other are formed in an edge portion of the upper circuit layer 120. The vias 118 and 126 may include input/output signal terminals, a power terminal, and a ground terminal. The vias 118 and 126 may be connected to each other in the PCB 100 via the bond fingers 128 and the printed circuit patterns. In the present embodiment, the vias 118 and 126 are disposed in the edge portion of the upper circuit layer 120.

However, the vias 118 and 126 may be disposed at various locations, according to user convenience. A printed circuit pattern arranged in the upper circuit layer 120 of the PCB 100, including the chip mount area 122, the bond fingers 128, and the vias 118 and 126, is defined as a first circuit pattern.

When a semiconductor chip that is mounted on the chip mount area 122 operates at a high operating frequency, noise by electromagnetic interference (EMI) may occur. In particular, when the vias 118 and 126 are vertically formed in the PCB 100 so as to connect multi-layered interconnection layers to one another, the noise by EMI is coupled with resonance generated in circuit patterns of the PCB 100 having multiple layers.

Thus, a resonance mode is generated in the PCB 100, which results in the occurrence of EMI, and EMI is transmitted to the outermost portion of the PCB 100 in the form of a surface wave. When a semiconductor device operates at a high speed, the occurrence of noise by EMI, in the edge portion of the PCB 100, needs to be prevented.

To prevent the occurrence of noise by EMI, in the present embodiment, EMI blocking vias 130 that are connected to a ground plane are disposed in an edge portion of the first circuit pattern of the upper circuit layer 120, including the chip mount area 122, the bond fingers 128, and the vias 118 and 126.

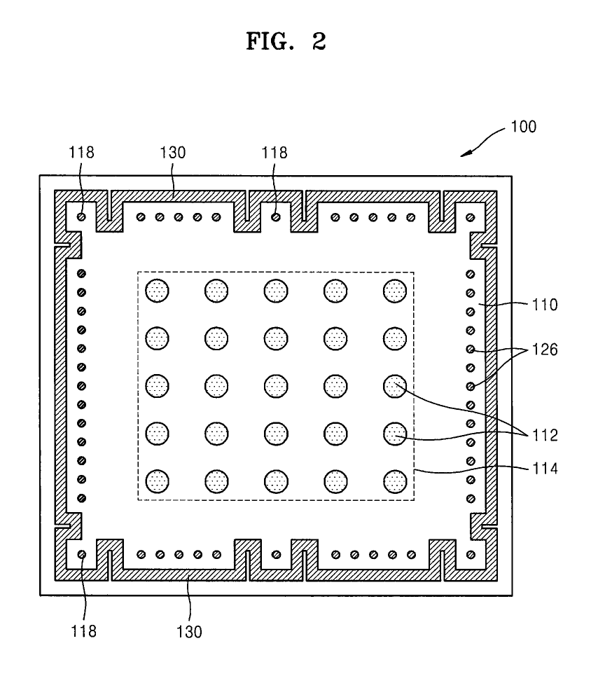

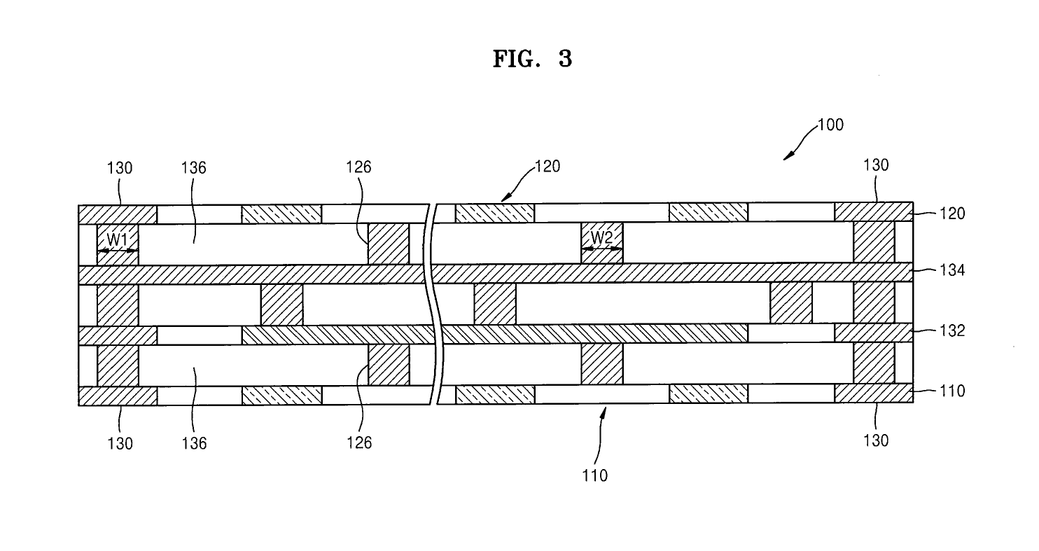

The EMI blocking vias 130 may be formed so as to penetrate the upper circuit layer 120, intermediate circuit layers 132 and 134 (see FIG. 3), and a lower circuit layer 110 (see FIGS. 2 and 3) of the PCB 100, and have a closed curve shape, viewed from the upper circuit layer 120. In addition, the EMI blocking vias 130 are arranged so as to surround the power terminal 118, and thus, may effectively block the noise by EMI in the semiconductor package.

FIG. 2 is a bottom view of the PCB 100 for a semiconductor package, according to an embodiment of the present invention.

Referring to FIG. 2, the PCB 100 includes the lower circuit layer 110 at a lower portion thereof. The lower circuit layer 110 includes solder ball pads 112 that are disposed within the region 114 illustrated by a dashed line, where a semiconductor package is to be formed and serve as an external connection terminal. The plurality of vias 118 and 126 that vertically connect printed circuit patterns (not shown) to one another are formed in an edge portion of the lower circuit layer 110.

The vias 118 and 126 may be organically connected to the vias 118 and 126 of the upper circuit layer 120. The vias 118 and 126 may include input/output signal terminals, the power terminal, and a ground terminal. The vias 118 and 126 may be connected to each other in the PCB 100 through the solder ball pads 112 and the printed circuit patterns.

In the present embodiment, the vias 118 and 126 are disposed in the edge portion of the lower circuit layer 110. In some embodiments, however, the vias 118 and 126 may be disposed at various locations, according to user convenience. A printed circuit pattern arranged in the lower circuit layer 110 of the PCB 100, including the solder ball pads 112 and the vias 118 and 126, is defined as a third circuit pattern.

In the lower circuit layer 110 of the PCB 100, the EMI blocking vias 130, which have been described above with reference to FIG. 1, are arranged along an edge portion of the third circuit pattern. The EMI blocking vias 130 may be formed so as to penetrate the upper circuit layer 120, the intermediate circuit layers 132 and 134(see FIG. 3), and the lower circuit layer 110 of the PCB 100 and have a closed curve shape, viewed from the lower circuit layer 110. In addition, the EMI blocking vias 130 are arranged so as to surround the power terminal 118, and thus, may effectively block noise by EMI in the semiconductor package.

FIG. 3 is a cross-sectional view of the PCB 100 for a semiconductor package, according to an embodiment of the present invention.

Referring to FIG. 3, the PCB 100 may be a multi-layered substrate having at least four metal layers. The PCB 100 includes the upper circuit layer 120 illustrated in FIG. 1 that has the first circuit pattern formed therein, the intermediate circuit layers 132 and 134 that are disposed below the upper circuit layer 120 and have a second circuit pattern formed therein, the lower circuit layer 110 that is disposed below the intermediate circuit layers 132 and 134 and has the third circuit pattern formed therein, insulating layers 136 that are disposed between the first and second circuit layers and between the second and third circuit patterns, the vias 118 and 126 that vertically connect the first, second, and third circuit patterns, and EMI blocking vias 130 that are arranged along edge portions of the first, second and third circuit patterns and are connected to a ground layer.

The intermediate circuit layers 132 and 134 may include a power layer 132 and a ground layer 134. In an embodiment, the intermediate circuit layers 132 and 134 may consist of at least two metal layers. The EMI blocking vias 130 may be formed so as to penetrate the upper circuit layer 120, the intermediate circuit layers 132 and 134, and the lower circuit layer 110. In this regard, a width W1 of the EMI blocking vias 130 is formed larger than a width W2 of the vias 118 and 126. Therefore, the noise by EMI may be effectively blocked.

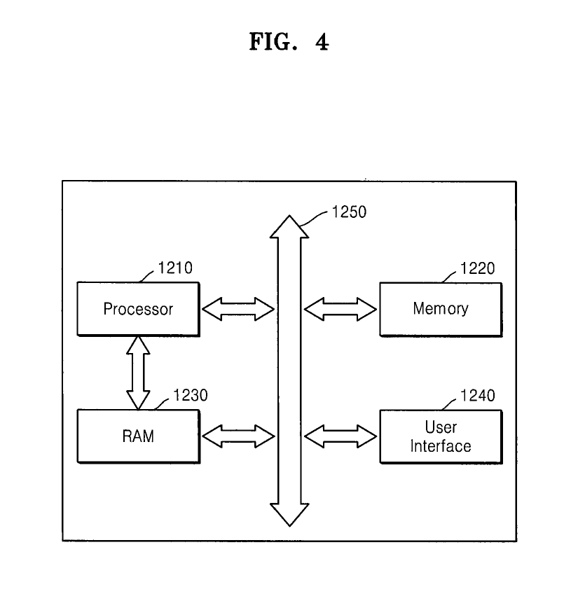

FIG. 4 is a block diagram illustrating an electronic system including a PCB for a semiconductor package, according to an embodiment of the present invention.

As illustrated in FIG. 4, the electronic system may include a semiconductor package manufactured using the PCB 100 illustrated in FIGS. 1 through 3. The electronic system may be used in mobile devices, computers, or the like. Referring to FIG. 4, the electronic system includes a processor 1210, a memory 1220, a random access memory (RAM) 1230, and a user interface 1240. The processor 1210, the memory 1220, the RAM 1230, and the user interface 1240 may data-communicate with each other via a bus 1250. The processor 1210 may execute programs and control the electronic system. The RAM 1230 may be used as an operation memory of the processor 1210. The processor 1210 and the RAM 1230 is formed in a single semiconductor package

For example, the semiconductor package manufactured using the PCB 100 illustrated in FIGS. 1 through 3 may be included in the memory 1220, the RAM 1230, and the processor 1210 of the electronic system according to the present embodiment.

The user interface 1240 may be used to input or output data to or from the electronic system. The memory 1220 may store code for operating the processor 1210, data that is processed by the processor 1210, or externally input data. The electronic system illustrated in FIG. 4 may be used in electronic control devices of various types of electronic devices. In addition, the electronic system may be used in portable game machines, portable notebook computers, MP3 players, navigation systems, solid state disks (SSDS), automobiles, and household appliances.

As described above, according to the one or more embodiments of the present invention, first, EMI blocking vias are inserted into a PCB for a semiconductor package which has a multi-layered structure along an edge portion of the PCB, whereby a noise that is radiated from the edge portion of the PCB may be prevented. Second, the noise by EMI may be prevented by modifying a structure of the PCB by a simple design change, and thus, such a method may reduce a manufacturing time and manufacturing costs, as compared to other typical methods, a method of using a metal cap or a method of changing a circuit design. Third, the EMI blocking vias are formed in edge portions of printed circuit patterns, and thus, are advantageous in terms of space utilization. In addition to blocking effects of the EMI blocking vias, the EMI blocking vias are effective to enhance ground in the PCB. Therefore, the semiconductor package may have stable signal characteristics.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A printed circuit board for a semiconductor package, the printed circuit board comprising:
an upper circuit layer in which a first circuit pattern is formed;
an intermediate circuit layer that is disposed below the upper circuit layer and has a second circuit pattern formed therein;
a lower circuit layer that is disposed below the intermediate circuit layer and has a third circuit pattern formed therein;
an insulating layer disposed between the first and second circuit patterns and between the second and third circuit patterns;
vias that vertically connect the first, second and third circuit patterns; and
electromagnetic interference (EMI) blocking vias that are arranged along edge portions of the first, second and third circuit patterns and are connected to a ground layer.

2. The printed circuit board of claim 1, wherein the EMI blocking vias penetrate the upper circuit layer, the intermediate circuit layer, and the lower circuit layer.

3. The printed circuit board of claim 1, wherein the EMI blocking vias have a closed curve shape, viewed from planes of the upper and lower circuit layers.

4. The printed circuit board of claim 1, wherein the printed circuit board comprises at least two of the intermediate circuit layers.

5. The printed circuit board of claim 4, wherein the at least two of the intermediate circuit layers comprise a ground layer and a power layer.

6. The printed circuit board of claim 1, wherein the EMI blocking vias are arranged so as to surround a power terminal in the first, second and third circuit patterns.

7. The printed circuit board of claim 1, wherein a width of the EMI blocking vias is larger than a width of the vias.
